(19) United States
(12) Patent Application Publication
(10) Pub. No.: US 2023/0198276 A1
(43) Pub. Date: Jun. 22, 2023

(54) INTELLIGENT BATTERY CELL SYSTEM WITH INTEGRATED CELL MONITORING

(71) Applicant: STAFL Systems, LLC, San Francisco, CA (US)

(72) Inventor: Erik Stafl, San Francisco, CA (US)

(21) Appl. No.: 17/645,443

(22) Filed: Dec. 21, 2021

(51) Int. Cl. H02J 7/00; H01M 10/0525; H01M 10/48; H01M 10/615; H01M 10/625; H01M 10/44; H01M 10/42; G01R 31/367; G01R 31/382; G01R 31/392

(52) U.S. Cl. CPC H02J 7/005; G01R 31/367; G01R 31/382; G01R 31/392; H01M 10/48; H01M 10/425; H01M 10/443; H01M 10/0525; H01M 10/615; H01M 10/625; H02J 7/0031; H02J 7/00032; H02J 7/0048; H01M 2010/4271; H01M 2220/20

(57) ABSTRACT

Disclosed is an intelligent battery cell system (iBCS) comprising a battery cell, a battery monitoring system (BMS) integrated with the battery cell, and a housing. The BMS is both in signal communication with and physically attached to the battery cell within the housing and the BMS includes a processor and a memory, where the memory has a machine-readable medium having encoded thereon machine-executable instructions that cause the processor to perform one or more process steps in the operation of the BMS.

### BACKGROUND

### Field

The present disclosure relates in general to battery systems, and more specifically, to systems for battery system management.

### Related Art

At present, both battery cell technology and the associated fabrication techniques to produce these new types of batteries are improving rapidly. These improvements have led to greater development and use of battery powered devices and vehicles. Moreover, these improvements have also increased the use of batteries for the energy storage of power generation systems such, for example, solar and wind powered systems.

Unfortunately, at present the use of battery cell packs often raises a number of design challenges in engineering systems that utilize these battery cell packs. Design challenges may be particularly significant in the context of large format battery packs that include large numbers of individual battery cells, where each battery cell has a high energy density.

For example, these types of battery cell packs may produce high voltage levels with the capacity to produce very high energy discharge rates. As such, for safety and reliability considerations, it may be very important to maintain electrical isolation of these battery cell packs from, e.g., surrounding systems and people, and to maintain other safe operating conditions. Attempts to address these problems have included the use of battery monitoring systems to monitor e.g. cell voltages and/or temperatures. A conventional battery monitoring system (BMS) is typically a circuit board that may reside within, on or outside of a battery cell support frame housing a large number of battery cells. The conventional BMS is typically interconnected with other components in the battery cell pack via, e.g., voltage sensing lines, temperature sensors and the like. In many battery cell packs, a sizable array of voltage sensing lines and temperature sensors extending around and through the pack contributes meaningfully to pack cost and complexity of pack assembly, while adding constraints on the pack’s physical form factor. However, as the use of battery powered devices, vehicles, and storage devices continue to grow, there is a need to simplify the BMS and battery cell pack configuration to increase integration, increase format flexibility, improve performance, improve manufacturability, and/or reduce cost of these systems.

### SUMMARY

An intelligent battery cell system (iBCS) comprising a battery cell, a battery monitoring system (BMS) integrated with the battery cell, and a housing is disclosed. The BMS is both in signal communication with and physically attached to or otherwise collocated with the battery cell within the housing and the BMS includes a processor and a memory, where the memory has a machine-readable medium having encoded thereon machine-executable instructions that cause the processor to perform one or more process steps in the operation of the BMS. A number of such iBCS may then be combined for form a battery cell pack.

In an example of operation, the iBCS performs a method that includes powering the BMS directly with the battery cell; measuring a plurality of characteristics of the battery cell with a plurality sensors of the BMS; generating state values from the measured plurality of characteristics with the BMS utilizing a processor; and transmitting the state values to a master controller that is external to the iBCS and is in signal communication with the BMS.

Other devices, apparatuses, systems, methods, features, and advantages of the invention will be or will become apparent to one with skill in the art upon examination of the following figures and detailed description. It is intended that all such additional devices, apparatuses, systems, methods, features, and advantages be included within this description, be within the scope of the invention, and be protected by the accompanying claims.

### BRIEF DESCRIPTION OF THE FIGURES

The invention may be better understood by referring to the following figures. The components in the figures are not necessarily to scale, emphasis instead being placed upon illustrating the principles of the invention. In the figures, like reference numerals designate corresponding parts throughout the different views.

FIG. 1 is a system block diagram of an example of an implementation of an intelligent battery cell system (iBCS) within a battery-powered system in accordance with the present disclosure.

FIG. 2 is a system block diagram of an example of an implementation of control signaling between a battery monitoring system (BMS) and a vehicle management unit (VMU) of the battery-powered system shown in FIG. 1 in accordance with the present disclosure.

FIG. 3 is a system block diagram of an example of an implementation of a BMS shown in FIG. 2 in accordance with the present disclosure.

FIG. 4 is a graph of an example of a plot of battery pack temperature versus voltage level in accordance with the present disclosure.

FIG. 5 is a flowchart of an example of an implementation of a method performed by the iBCS in operation in accordance with the present disclosure.

### DETAILED DESCRIPTION

Disclosed is an intelligent battery cell system (iBCS) comprising a battery cell, a battery monitoring system (BMS) integrated with the battery cell, and a housing. The BMS is both in signal communication with and physically attached to or otherwise collocated with the battery cell within the housing and the BMS includes a processor and a memory, where the memory has a machine-readable medium having encoded thereon machine-executable instructions that cause the processor to perform one or more process steps in the operation of the BMS.

In an example of operation, the iBCS performs a method that includes powering the BMS directly with the battery cell; measuring a plurality of characteristics of the battery cell with a plurality of sensors of the BMS; generating state values from the measured plurality of characteristics with the BMS utilizing a processor; and transmitting the state values to a master controller that is external to the iBCS and is in signal communication with the BMS.

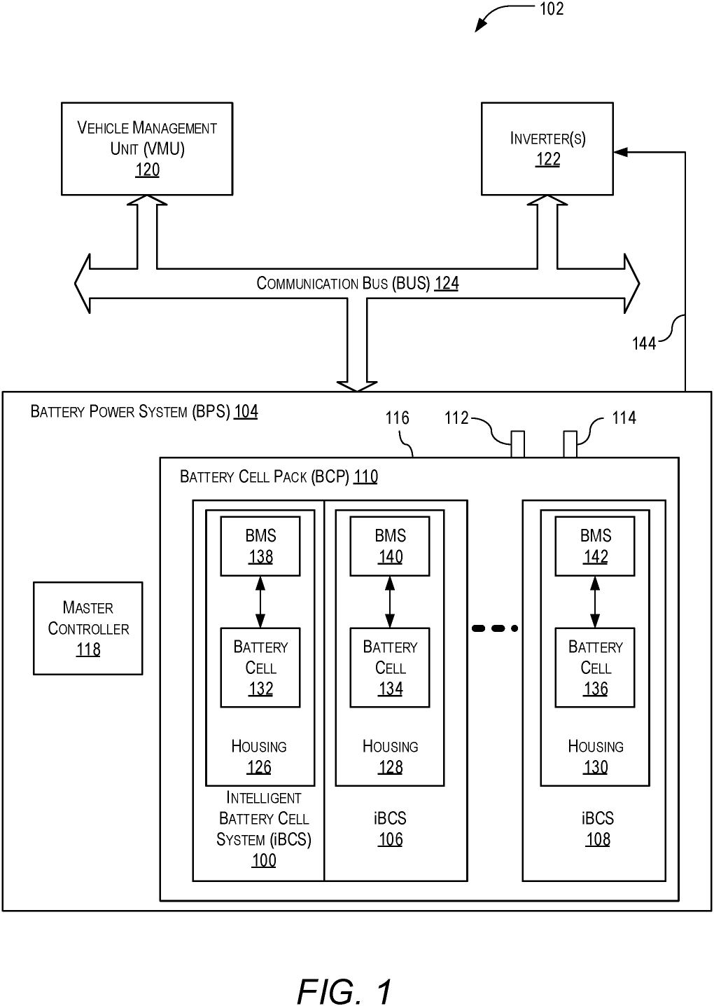

In FIG. 1, a system block diagram of an example of an implementation of an iBCS 100 within a battery-powered system 102 is shown in accordance with the present disclosure. In this example, the iBCS 100 is part of a battery power system (BPS) 104 having at least one iBCS (i.e., iBCS 100) or a plurality of iBCS s 100, 106, and 108. If the BPS 104 includes a plurality of iBCSs 100, 106, and 108, the plurality of iBCSs 100, 106, and 108 may be arranged as a battery cell pack (BCP) 110 within the BPS 104 having a positive terminal 112 and negative terminal 114 extending from an outer surface 116 of the BCP 110.

In some embodiments, the BCP 110 is a high-density battery pack that may include a large number of iBCS. Because each iBCS may be a modular, independently operable, independently-manageable power source, battery system design may be substantially simplified as compared to alternative traditional battery cell pack designs in which voltage and temperature sensing components must be carefully designed and routed around and through a battery cell pack.

In this example, the BPS 104 also includes a master controller 118 that is in signal communication with the plurality of iBCSs 100, 106, 108, as described further hereinbelow. The BPS 104 is in signal communication with both a vehicle management unit (VMU) 120 and one or more inverters 122 via a communication bus (BUS) 124. In this example, each iBCS 100, 106, or 108 includes a housing 126, 128, or 130, a battery cell 132, 134, or 136, and a BMS 138, 140, or 142, respectively. The housing 126, 128, or 130 may be, for example, a sealed battery pouch or solid housing having a flat or cylindrical shape. In this example, each BMS 138, 140, or 142 is integrated into the corresponding iBCS 100, 106, or 108 and is in signal communication with and physically attached to or otherwise collocated with each corresponding battery cell 132, 134, or 136, respectively. In some embodiments, BMS 138, 140, 142 may be implemented using a sytem-on-a-chip architecture, imposing de minimis physical space requirements within an iBCS housing 126, 128, 130. In some embodiments, housing 126, 128, 130 may have a physical form factor similar or identical to a housing of conventional battery cells with standardized form factors, potentially enabling iBCSs such as iBCS 100, 106, 108 to be readily substituted for conventional battery cells in some system component designs.

In this example, the battery-powered system 104 may be, for example, an electric vehicle or electrical storage system for a power generation system such as, for example, a solar power system. Moreover, the battery cells 132, 134, or 136 may each be, for example, Lithium-Ion battery cells.

In an example of operation, the each BMS 138, 140, and 142 communicates directly to the master controller 118, the master controller 118 communicates with the VMU 120 via the BUS 124, and the BPS 104 drives the inverters 122 via power output line 144. The BMS 138, 140, 142 may optionally communicate with the master controller 118 either wirelessly or via electrical signal paths (not shown) between each BMS 138, 140, and 142 and the master controller 118. The electrical signal paths may also include power line communication (PLC). It is appreciated by those of ordinary skill in the art that PLC, also known as Power Line Telecommunications (PLT) is the communication technology which uses the existing public and private wiring for the transmission of the signals. Using PLC communication signals, high-speed data, voice and video are transmitted over low-voltage power lines.

In many embodiments, it will be preferable to implement wireless communication between BMS 138, 140, 142 and master controller 118, thereby simplifying assembly of BPS 104 and reducing component count. If wireless, the individual BMSs 138, 140, and 142 would each include a wireless transceiver implemented within master controller 118. As an example, each BMS 138, 140, and 142 and the master controller 118 may each include a wireless transceiver configured to transmit via, for example, Bluetooth®, a 2.4 GHz encrypted frequency hopping protocol, or other encrypted, low-power, low-range wireless communications.

In vehicle applications, the BUS 124 is commonly implemented using the CANBUS standard (e.g., Controller e a Network BUS). The VMU 120 in turn transmits control signals to the inverters 122 that are, for example, vehicle drive inverters, which are driven by current from the BPS 104 via power output line 144, and which inverters 122 in turn supply power to electric motors or other loads (not shown) within the battery-powered system 102. It is appreciated by those of ordinary skill in the art that while the VMU 120 is referred to as a vehicle management unit, it is contemplated and understood by those of ordinary skill in the art that in non-vehicular applications (such as for stationary energy storage or other industrial applications), the VMU 120 may instead be another system controller that is external to BPS 104 and involved in control of an electrical load to be powered by the BPS 104.

In this example, each BMS 138, 140, and 142 includes a number of sensors that are in signal communitcation with and/or physically attached to reach corresponding battery cell 132, 134 and 136, respectively. These sensors may be, for example, voltage, current, temperature, and/or pressure sensors and the each BMS 138, 140, and 142 utilizes these individual sensors to monitor the operational conditions associated with various portions of each individual battery cell 132, 134, or 136. In some embodiments, some or all of such sensors may be implemented by a BMS as partof a system–on–a–chip construction. In other embodiments, some or all of such sensors maybe implemented using separate componets within a housing 126, 128, 130.

It is appreciated by those of ordinary skill in the art that the use of these types of sensors are well known in the art and therefore are not described or illustrated herein, as being inherent to most battery management systems. However, what is not known in the art is the physical and electrical integration of a BMS with an individual battery cell within a common housing where the sensors of the BMS monitor the individual battery cell and communicate that information to a master controller as disclosed in the present disclosure.

In this example, the BMSs 138, 140, and 142 are preferably coated with a protective material to avoid corrosion and the battery cell 132, 134, and 136 chemicals adversely reacting with the silicon and other material of the electronic boards that utilized to fabricate the BMSs 138, 140, and 142. By electrically integrating a BMS (preferebly designed for low power consumption) with a corresponding battery cell, the BMS will always be powered up since during expected operating conditions, the battery cell should always provide at least a small about of power through its lifespan of operation.

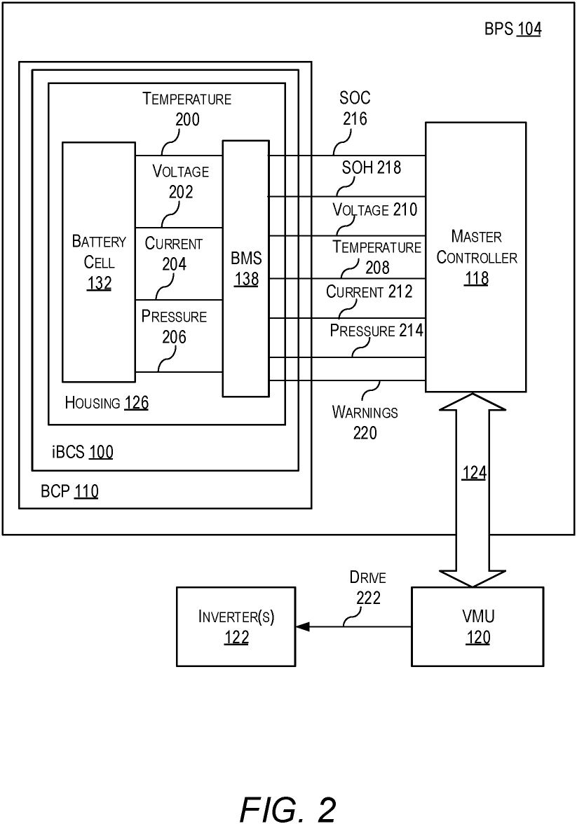

In FIG. 2, a system block diagram of an example of an implementation of control signaling between a single BMS (i.e., BMS 138) and the VMU 120 is shown in accordance with the present disclosure. Only a single iBCS (i.e., iBCS 100) is shown in this example but it is appreciated by those of ordinary skill in the art that all of the other iBCSs (i.e., iBCS 106 and 108) of the BCP 110 also have the same control signaling configuration between the corresponding BMS (i.e., BMS 140 and 142) of the respective iBCS and the VMU 120. In this example, as described earlier, the iBCS 100 includes the battery cell 132 and BMS 138; and the BMS 138 utilizes numerous sensors and/or electrical access points attached to the battery cell 132 within housing 126 to measure the operating parameters associated with the battery cell 132.

In an example of operation, the BMS 138 measures, for example, the temperature 200, voltage 202, current 204, and/or pressure 206 values of the battery cell 132. Because BMS 138 will preferably be housed with battery cell 132 within housing 126, in some embodiments sensors may effectively monitor ambient battery cell operating conditions while being implemented entirely within a common integrated circuit or small form-factor printed circuit board as other BMS components. The BMS 138 then produces a digital temperature 208, digital voltage 210, digital current 212, and/or digital pressure 214 state values that are transmitted to the master controller 118. The master controller 118 then conveys the state values to the VMU 120 via the BUS 124 that may be a CANBUS. The state values/information may include direct measurements of battery cell 132, some subset of such measurements, and/or information derived from such measurements. Other common parameters provided to VMU 120 by BMS 138 via the master controller 118 include a state of charge (SOC) output 216 (e.g. the present amount of energy stored in the battery cell 132, potentially expressed as a percentage of maximum capacity), state of health (SOH) 218 (e.g. the recoverable capacity of the iBCS 100, typically expressed as a fraction of beginning of life capacity), one or more voltage levels 210, one or more temperature readings 208 within the battery cell 132, and battery cell current levels 212. The BMS 138 may also provide a variety of warnings and fault notifications 220 that may be sent to the VMU 120 via the master controller 118. The battery cell operating parameters 208 through 220 may then be considered by VMU 120 in controlling system operations (such as driving 222 inverters 122 or otherwise implementing desired vehicle operations, without causing the battery cell 132 to exceed permissible operating conditions). For example, the VMU 120 may observe the battery cell 132 temperature signals 208 indicating that the BCP 110 is reaching a maximum permissible operating temperature, and subsequently limit maximum drive level conveyed to inverters 122 by VMU 120 in drive signal 222, regardless the vehicle throttle position or other performance demands.

In this example, the master controller 118 is a device that is configured to receive all of the state values/information from all of the individual BMSs 138, 140, and 142 and then combines, analyzes, and/or organizes all of the received state values/information from all of the individual BMSs 138, 140, and 142 into a composite set of state values/information that is conveyed to the VMU 120. In this fashion, the VMU 120 receives data that is relevant to the state and performance of the BCP 110.

As such, the master controller 118 is device that includes one or more processors, a memory, software/firmware, and interfaces to communicate with both the individual BMSs (i.e., BMS 138, 140, and 142) and the VMU 120 via the BUS 124.

In this disclosure, it is appreciated by those of ordinary skill in the art that the circuits, components, modules, and/or devices of, or associated with, the BPS 102, BCP 110, and other systems disclosed in this disclosure are described as being in signal communication with each other, where signal communication refers to any type of communication and/or connection between the circuits, components, modules, and/or devices that allows a circuit, component, module, and/or device to pass and/or receive signals and/or information from another circuit, component, module, and/or device. The communication and/or connection may be along any signal path between the circuits, components, modules, and/or devices that allows signals and/or information to pass from one circuit, component, module, and/or device to another and includes wireless or wired signal paths. The signal paths may be physical, such as, for example, conductive wires, electromagnetic wave guides, cables, attached and/or electromagnetic or mechanically coupled terminals, semi-conductive or dielectric materials or devices, or other similar physical connections or couplings. Additionally, signal paths may be non-physical such as free-space (in the case of electromagnetic propagation) or information paths through digital components where communication information is passed from circuit, component, module, and/or device to another in varying digital formats without passing through a direct electromagnetic connection.

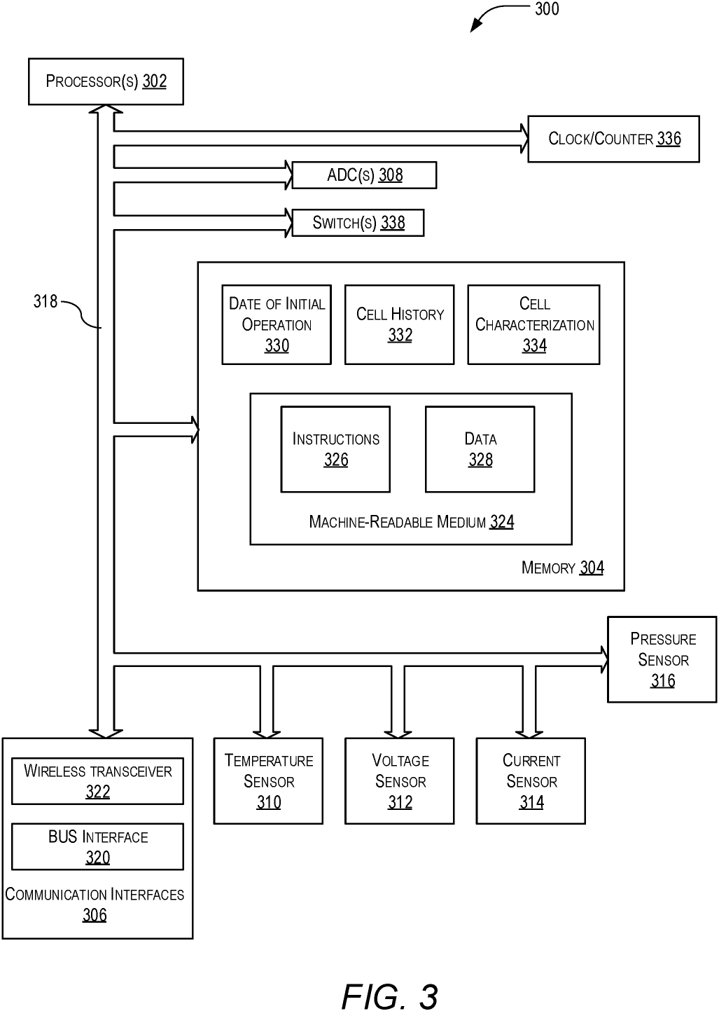

Turning to FIG. 3, a system block diagram of an example of an implementation of a BMS 300 is shown in accordance with the present disclosure. The BMS 300 may be any of the BMS shown in FIGS. 1 and 2 (e.g. BMS 132, 134 or 136). The BMS 300 includes one or more processors 302, a memory 304, and a plurality of communication interfaces 306. The BMS 300 may also include one or more analog-to-digital converters (ADCs) 308 and one or more sensors. The one or more sensors may include a temperature sensor 310, voltage sensor 312, current sensor 314, and/or pressure sensor 316. The one or more processors 302, memory 304, one or more communication interfaces 306, one or more ADCs 308, and one or more sensors 310, 312, 314, and 316 are in signal communication with each other via an internal system bus 318. The one or more communication interfaces 306 includes, for example, a BUS interface 320 for communicating with the BUS 124 and a wireless transceiver 322 for communicating wirelessly with the master controller 118.

As utilized in present disclosure, the one or more processors 302 may represent, for example, a CPU-type processing unit, a GPU-type processing unit, a field-programmable gate array (“FPGA”), another class of digital signal processor (“DSP”), or other hardware logic components that may, in some instances, be driven by a CPU. For example, and without limitation, illustrative types of hardware logic components that may be utilized include Application-Specific Integrated Circuits (“ASICs”), Application-Specific Standard Products (“ASSPs”), System-on-a-Chip Systems (“SOCs”), Complex Programmable Logic Devices (“CPLDs”), etc.

The memory 304 includes a machine-readable medium 324 having encoded thereon machine-executable instructions 326 that cause the one or more processors 302 to perform one or more process steps in the operation of the BMS 300. As utilized in the present disclosure, the machine-readable medium 324 (also known as a machine-readable media, or computer-readable medium or media), may store the machine-executable instructions 326 executable by the one or more processors 302. The computer-readable media may also store instructions executable by external processing units such as a processor in the master controller 118. In this example, the machine-readable medium 324 may include computer storage media and/or communication media. Computer storage media may include one or more of volatile memory, nonvolatile memory, and/or other persistent and/or auxiliary computer storage media, removable and non-removable computer storage media implemented in any method or technology for storage of information such as computer-readable instructions, data structures, program modules, or other data. Thus, computer storage media includes tangible and/or physical forms of media included in a device and/or hardware component that is part of a device or external to a device, including but not limited to random access memory (“RAM”), static random-access memory (“SRAM”), dynamic random-access memory (“DRAM”), phase change memory (“PCM”), read-only memory (“ROM”), flash memory, or other storage device, and/or storage medium that can be used to store and maintain information for access by a computing device.

In this example, the machine-readable medium 324 includes a data store 328, where the data store 328 includes data storage such as a database, or other type of structured or unstructured data storage. The data store 328 may store data for the operations of processes, applications, components, and/or modules stored machine-readable medium 324 and/or executed by processor 302. For instance,in some examples, the data store 328 may store battery cell state values/information and operating parameters that are measured by the temperature sensor 310, voltage sensor 312, current sensor 314, and pressure sensor 316.

The memory 304 may also include a date of initial operation 330, battery cell history data 332 about the battery cell corresponding to the BMS 300, and battery cell characterization data 334. The date of initial operation 330 is the stored date value of when the corresponding battery cell was initially placed into service so as to allow calculation of the age of the battery cell. The battery cell history data 332 may include various types of historical battery cell operating information, for example, historical duty cycles, peak and sustained discharge rates, prior operating temperatures, battery cell age (based on the date of initial operation 330), and the like. The battery cell characterization data 334 may include information characterizing the physical or electrochemical characteristics of the battery cell, including, without limitation, information descriptive of the response of the battery cell to various conditions. The battery cell characterization data 334 may also include information provided by the manufacturer of the battery cell to enable the battery cell to operate within the operating parameters defined by the manufacturer.

The BMS 300 may also include a clock/counter 336 configured to allow the one or more processors 302 to determine the time the age of the battery cell as compared to the date of initial operation 330. The clock/counter 336 is also configured for timing and to allow the oneor more processors 302 to determine the operational parameters of the battery cell such as, for example, the duty cycle of the battery cell. In this example, the clock/counter 336 may include a first counter circuit configured to count the time that the battery cell has been operational since the preconfigure date of initial operation and a second counter circuit that is configured to determine the number of charge and discharge cycles that the battery cell has performed since the preconfigured date of initial operation of the battery cell.

Moreover, the BMS 300 may further include one or more switches 338. The one or more switches 338 may include a solid-state switch to disconnect the battery cell (i.e., battery cell 132) from an external circuit if the temperature or voltage of the battery cell go out of range. The one or more switches 338 may also include a heating element such as, for example, a switchable load and/or resistive element that may be switched across the cell voltage of the battery cell to self-discharge and heat-up the battery cell. This allows the battery cell to be pre-warmed for better performance since battery cells operate more efficiently at higher temperatures.

In operation, the one or more processors 302 of the BMS 300 may use the measured results from the sensors 310, 312, 314, and 316 to derive an SOE output, state data output(s) and warnings or other messaging that is transmitted via the BUS interface 320. The state data outputs may include, for example, analogous information to the BMS outputs 208-218 described in relation to FIG. 2.

In this example, the SOE output 216 may be determined in such a manner as to maintain the battery module within desired operating constraints. As an example, to determine the SOE output 216, the one or more processors 302 may perform, a calculation using at least one of the battery cell voltage measurements 202, current measurements 204, temperature measurements 200, battery cell history data 332 information, and cell characterization 334, in order to generate SOE output 216. To generate the SOE output 216, the one or more processors 302 may utilize, for example, a linear equation non-linear equation, or machine learning process.

In this example, the pressure sensor 316 may be a micro-electro-mechanical system (MEMS) pressure sensor that is physically attached to the battery cell or otherwise collocated with the battery cell within a common housing, and detects if the battery cell housing swells. If the battery cell swells, a failure alarm may be triggered to prevent battery cell failure or other safety issues.

It is appreciated by those of ordinary sill in the art that in the previous descriptions, the information flows from a BMS (i.e., 138, 140, and/or 142) to the master controller 118 to the VMU 120. However, the master controller 118 may also be configured to transmit information (e.g., command signals) to an individual BMS (i.e., 138, 140, and/or 142) to disconnect the cell, discharge the cell, heat up the cell, etc. In this example, the master controller 118 is capable of turning on or off cell balancing, heating, and performing a full internal disconnect within the cell itself.

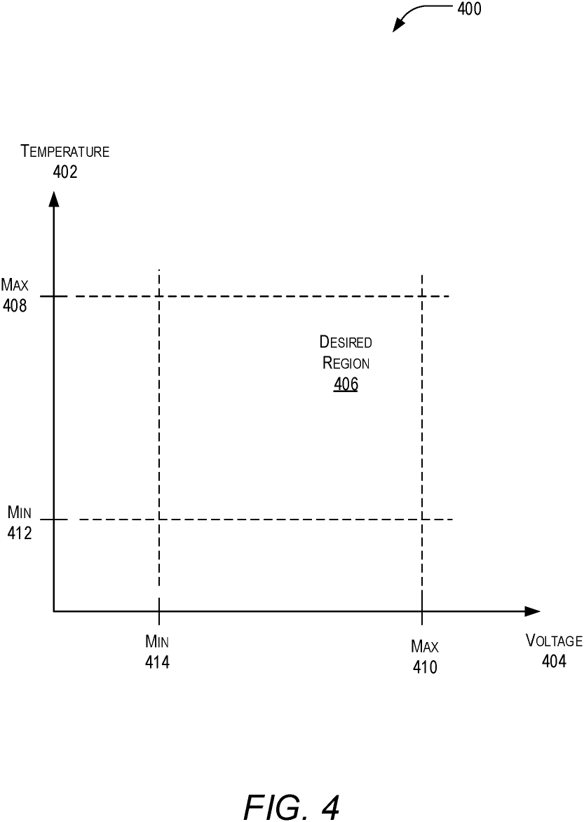

In FIG. 4, a graph 400 of an example of a plot of battery pack temperature 402 versus voltage level 404 is shown in accordance with the present disclosure. The SOE output 216 may be optimized by maintaining the operating ranges of the temperature and voltage within a desired voltage and temperature region 406 as shown.

In this example, operating temperatures in excess of maximum temperature threshold 408 and/or operating voltage levels in excess of maximum voltage threshold 410 may, for example, expose the battery cell to unacceptable risk of damage or safety concerns (such as thermal runaway). Temperatures below minimum temperature threshold 412 may, for example, yield unacceptably reduced performance and/or cell damage. Voltage levels below lower threshold 414 may, for example, result in lithium plating problems. Thus, in operation, the BMS 300 may determine SOE output 216 so that a vehicle or other system operating within the SOE-specified load range will maintain the battery cell within the desired voltage and temperature region 406. As described earlier, the BMS includes a solid-state switch (i.e., switches 338) in signal communication with the battery cell, where the solid-state switch is configured to disconnect the battery cell from the iBCS if the temperature values of voltage, current, or temperature are outside of a predetermined range of operation (i.e., outside of voltage and temperature region 406 for voltage and temperature) for the voltage, current, or temperature, respectively.

While the desired voltage and temperature region 406 is a simple rectangular region defined by fixed maximum and minimum voltages and temperatures, it is contemplated and understood that, even in embodiments with SOE defined to maintain desired operating voltage and temperature relationships, other relationships may be defined. In some embodiments, voltage and temperature thresholds may be dynamic, and based in part on other information, such as the battery cell history data 332 and the battery cell characterization data 334. For example, as the battery cell ages, it may be desirable to reduce maximum operating temperatures. As another example, if historical battery cell operating conditions characterized in memory 304 resulted in escalating battery cell temperatures, subsequent SOE outputs may be determined to reduce threshold voltages and/or temperatures to avoid such escalation. In yet other example, voltage thresholds may be a function of temperature, and vice versa, such that desired region 406 is expressed as a curved region. These and other types of relationships may be utilized in order to generate SOE output 216.

In some applications, it may be desirable to enable swapping of the iBCS (i.e., iBCS 100). For example, in electric vehicle applications, it may be desirable to enable battery cells to be swapped when a battery cell’s state of health falls below a threshold level, in response to a malfunction. By including memory 304 and calculating the SOE output 216 locally, within the iBCS, historical operating data of the battery cell history data 332 and battery cell characterization data 334 stays within the iBCS. Thus, rather than having to “reset” such information with each iBCS, installation of a substitute battery module will provide the receiving system with rich information for use in determining the SOE output 216. In-module storage and utilization of the historical operating data (i.e., the battery cell history data 332) and/or the battery cell characterization data 334 may be similarly (or even more) beneficial in other, non-vehicular applications, such as stationary energy storage.

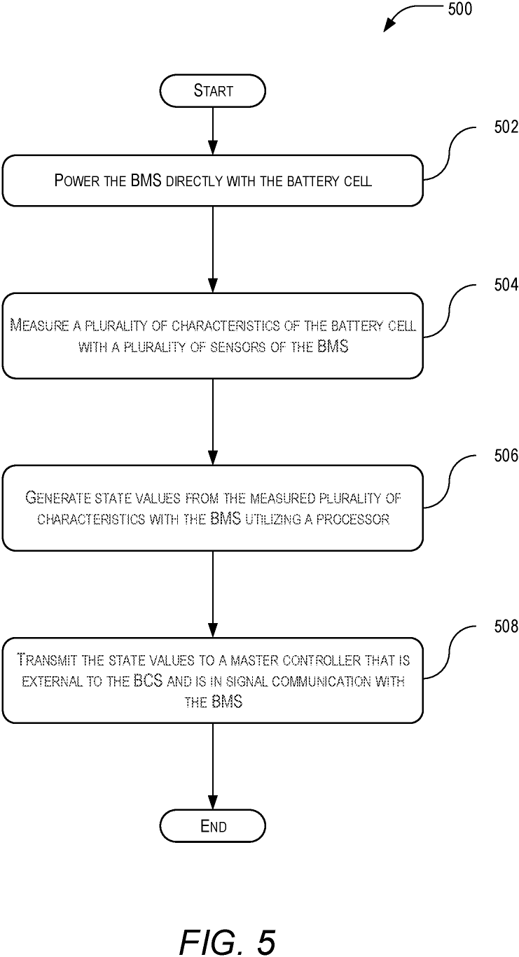

Turning to FIG. 5, a flowchart of an example of an implementation of a method 500 performed by the iBCS in operation in accordance with the present disclosure. The method 500 starts by powering 502 the BMS 300 directly with the battery cell and measuring 504 a plurality of charateristics of the battery cell with a plurality of sensors 310, 312, 314, and 316 of the BMS 300. The method 500 then generates 506 state values from the measured plurality of characteristics with the BMS utilizing a processor and transmits 508 the state values to the master controller 118 that is external to the iBCS 100 and is in signal communication with the BMS. The method 500 then ends. As described earlier, the BMS 300 performs all of the steps of the method 500 with the one or more processors 302 utilizing the machine-executable instructions 326 that are encoded on the machine-readable medium within the memory 304.

In this example, the measuring 504 the plurality of characteristics of the battery cell includes measuring a voltage produced by the battery cell with the voltage sensor 312, measuring a current produced by the battery cell with the current sensor 314, and measuring a temperature produced by the battery cell with the temperature sensor 310. The method 500 may also include disconnecting the battery call from the iBCS 100 if the measured values of voltage, current, or temperature are outside of a predetermined range of operation for the voltage, current, or temperature, respectively (e.g., the desired voltage and temperature region 406 as shown in FIG. 4).

In addition, or alternative to, the measuring 504 the plurality of characteristics of the battery cell includes measuring a pressure produced by the battery cell with the pressure sensor 316. The method 500 may then disconnect the battery cell to stop a current flow from the battery cell if the measure pressure of the battery exceeds a pre-determined pressure value.

In this example, the transmitting 508 the state values to a master controller 118 may include wirelessly transmitting the state values from the BMS 300 to the master controller 118 with a wireless transeceiver at the BMS 300. The transmission may be via Bluethooth® or other wireless short-range, low-power, and encrypted means. Moreover, generating 506 the state values includes generating a state of charge (SOC) value for the battery cell utilizing the measured voltage, current, and temperature.

The method 500 may further include storing the measured plurality of characteristics of the battery cell in the memory 304 on the BMS 300. In addition, the method 500 may also further include counting the time that the battery cell has been operational with a first counter circuit (within the clock/counter 336) and determining an age of the battery cell utilizing the preconfigured date of initial operation 330 of the battery cell that is stored in the memory 304 and the counted time from the counter circuit. Moreover, in addition or alternative to, the method 500 may further include disconnecting the battery cell from the iBCS if the temperature values of voltage, current, or temperature are outside of a predetermined range of operation for the voltage, current, or temperature, respectively. In addition, the method 500 may further include switching a switchable load element across a cell voltage of the battery cell and self-discharging the battery cell which resulting in heating the battery cell.

It will be understood that various aspects or details of the disclosure may be changed without departing from the scope of the disclosure. It is not exhaustive and does not limit the claimed disclosures to the precise form disclosed. Furthermore, the foregoing description is for the purpose of illustration only, and not for the purpose of limitation. Modifications and variations are possible in light of the above description or may be acquired from practicing the disclosure. The claims and their equivalents define the scope of the disclosure. Moreover, although the techniques have been described in language specific to structural features and/or methodological acts, it is to be understood that the appended claims are not necessarily limited to the features or acts described. Rather, the features and acts are described as an example implementations of such techniques.

Conditional language such as, among others, “can,” “could,” “might” or “may,” unless specifically stated otherwise, are understood within the context to present that certain examples include, while other examples do not include, certain features, elements and/or steps. Thus, such conditional language is not generally intended to imply that certain features, elements and/or steps are in any way required for one or more examples or that one or more examples necessarily include logic for deciding, with or without user input or prompting, whether certain features, elements and/or steps are included or are to be performed in any particular example. Conjunctive language such as the phrase “at least one of X, Y or Z,” unless specifically stated otherwise, is to be understood to present that an item, term, etc. may be either X, Y, or Z, or a combination thereof.

Furthermore, the description of the different examples of implementations has been presented for purposes of illustration and description, and is not intended to be exhaustive or limited to the examples in the form disclosed. Many modifications and variations will be apparent to those of ordinary skill in the art. Further, different examples of implementations may provide different features as compared to other desirable examples. The example, or examples, selected are chosen and described in order to best explain the principles of the examples, the practical application, and to enable others of ordinary skill in the art to understand the disclosure for various examples with various modifications as are suited to the particular use contemplated.

It will also be understood that various aspects or details of the invention may be changed without departing from the scope of the invention. It is not exhaustive and does not limit the claimed inventions to the precise form disclosed. Furthermore, the foregoing description is for the purpose of illustration only, and not for the purpose of limitation. Modifications and variations are possible in light of the above description or may be acquired from practicing the invention. The claims and their equivalents define the scope of the invention.

The description of the different examples of implementations has been presented for purposes of illustration and description, and is not intended to be exhaustive or limited to the examples in the form disclosed. Many modifications and variations will be apparent to those of ordinary skill in the art. Further, different examples of implementations may provide different features as compared to other desirable examples. The example, or examples, selected are chosen and described in order to best explain the principles of the examples, the practical application, and to enable others of ordinary skill in the art to understand the disclosure for various examples with various modifications as are suited to the particular use contemplated.

What is claimed is:

1. An intelligent battery cell system (iBCS) comprising:
a battery cell;
a battery monitoring system (BMS) integrated with the battery cell; and
a housing containing the battery cell and BMS, wherein
the BMS is both in signal communication with and physically collocated with the battery cell within the housing and
the BMS includes a processor and a memory having a machine-readable medium having encoded thereon machine-executable instructions that cause the processor to perform one or more process steps in an operation of the BMS.

2. The iBCS of claim 1, wherein
the BMS further includes one more of: a voltage sensor, temperature sensor, and current sensor; and
the BMS, in operation, is configured to
measure one or more of the voltage, current, and temperature of the battery cell with the voltage sensor, current sensor, and temperature sensor, respectively, and
store the measured values of voltage, current, and/or temperature in the memory.

3. The iBCS of claim 2, wherein
the BMS further includes a first counter circuit, and
the BMS, operation, to determine an age the battery cell utilizing a preconfigured date of initial of the battery cell utilizing a preconfigured date of initial operation of the battery cell that is stored in the memory and the first counter circuit.

4. The iBCS of claim 3, wherein
the BMS further includes a second counter circuit, and
the BMS, in operation, is configured to determine a number of charge and discharge cycles that the battery cell has performed utilizing the preconfigured date of initial operation of the battery cell and the second counter circuit.

5. The iBCS of claim 4, wherein
the BMS further includes a solid-state switch in signal communication with the battery cell, and
the solid-state switch is configured to disconnect the battery cell from the iBCS if the temperature values of voltage, current, or temperature are outside of a predetermined range of operation for the voltage, current, or temperature, respectively.

6. The iBCS of claim 5, further including a heating element configured to heat the battery cell.

7. The IBCS of claim 5, wherein the heating element includes a switchable load element that is configured to switch across a cell voltage of the battery cell to self-discharge and heat up the battery cell.

8. The iDCS of claim 7, wherein
the BMS further includes a pressure sensor that is physically collocated with the battery cell within the housing, and
the BMS, in operation, is configured to determine a pressure value of the battery cell when the battery cell is in operation.

9. The iBCS of claim 2, wherein
the BMS includes a transceiver configured to communicate with a master controller, and
the BMS, in operation, is configured to transmit one or more of the voltage, current, temperature, and/or state values derived therefrom, to the master controller.

10. A method for monitoring a performance of a battery cell in an intelligent battery cell system (iBCS) having a battery monitoring system (BMS) integrated with the battery cell within a common housing, the method comprising:
powering the BMS directly with the battery cell;
measuring a plurality of characteristics of the battery cell with a plurality of sensors of the BMS;
generating state values from the measured plurality of characteristics with the BMS utilizing a processor; and
transmitting the state values to a master controller that is external to the iBCS and is in signal communication with the BMS.

11. The method of claim 10, wherein measuring the plurality of characteristics of the battery cell includes measuring a voltage produced by the battery cell with a voltage sensor, measuring a current produced by the battery cell with a current sensor, and measuring a temperature produced by the battery cell with a temperature sensor.

12. The method of claim 11, wherein
measuring the plurality of characteristics of the battery cell further includes measuring a pressure produced by the battery cell with a pressure sensor, and
the method further includes disconnecting the battery cell to stop a current flow from the battery cell if the measure pressure of the battery exceeds a pre-determined pressure value.

13. The method of claim 11, wherein transmitting the state values to a master controller includes wirelessly transmitting the state values from the BMS to the master controller with a wireless transceiver at the BMS.

14. The method of claim 11, wherein generating the state values includes generating a state of charge (SOC) value for the battery cell utilizing the measured voltage, current, and temperature.

15. The method of claim 14, further includes storing the measured plurality of characteristics of the battery cell in a memory on the BMS.

16. The method of claim 15, further including
counting a time that the battery cell has been operational with a first counter circuit; and
determining an age of the battery cell utilizing a preconfigured date of initial operation of the battery cell that is stored in the memory and the counted time from the counter circuit.

17. The method of claim 11, further including disconnecting the battery cell from the iBCS if the measured values of voltage, current, or temperature are outside of a predetermined range of operation for the voltage, current, or temperature, respectively.

18. The method of claim 11, further including
switching a switchable load element across a cell voltage of the battery cell,
self-discharging the battery cell, and
heating the battery cell as a result of self-charging the battery cell.
